(19) United States
(12) Patent Application Publication
(10) Pub. No.: US 2026/0082778 A1
(43) Pub. Date: Mar. 19, 2026

(54) DISPLAY DEVICE AND ELECTRONIC DEVICE INCLUDING THE SAME

(71) Applicant: Samsung Display Co., LTD., Yongin-si (KR)

(72) Inventor: CHUNGI YOU, Yongin-si (KR)

(21) Appl. No.: 19/185,613

(22) Filed: Apr. 22, 2025

(30) Foreign Application Priority Data
Sep. 13, 2024 (KR) 10-2024-0125489

(51) Int. Cl. H10K 59/131

(52) U.S. Cl. CPC H10K 59/131

(57) ABSTRACT

A display device includes: a substrate including a display area and a peripheral area surrounding the display area; sub-pixels disposed on the substrate in the display area; a first blocking structure disposed on the substrate in the peripheral area along an edge of the substrate in a plan view, to block crack propagation; a second blocking structure disposed on the substrate in the peripheral area between the display area and the first blocking structure in the plan view, to block moisture; and a crack detection structure disposed on the substrate in the peripheral area between the display area and the second blocking structure in the plan view, where the crack detection structure includes a lower line layer disposed on the substrate, a middle line layer which is disposed on the lower line layer and includes a crack detection line, and an upper line layer disposed on the middle line layer.

This application claims priority to Korean Patent Application No. 10-2024-0125489, filed on Sep. 13, 2024, and all the benefits accruing therefrom under 35 U.S.C. § 119, the content of which in its entirety is herein incorporated by reference.

### BACKGROUND

### 1. Field

Embodiments of the disclosure relate generally to a display device. More particularly, embodiments of the disclosure relate to a display device that provides visual information and an electronic device including the display device.

### 2. Description of the Related Art

With the development of information technology, the importance of a display device, which is a connection medium between a user and information, has been highlighted. For example, display devices such as liquid crystal display (LCD) device, organic light emitting diode (OLED) display device, plasma display panel (PDP) device, quantum dot display device or the like are widely used in various fields.

### SUMMARY

In general, a plurality of display panels may be formed on a mother substrate, and the plurality of display panels may be separated into individual display panels through a scribing process. In the process of cutting the mother substrate, cracks may occur in the display panels. Embodiments provide a display device including a detection structure for detecting cracks.

Embodiments provide an electronic device including the display device.

A display device according to an embodiment of the disclosure includes: a substrate including a display area and a peripheral area surrounding the display area; a plurality of sub-pixels disposed on the substrate in the display area; a first blocking structure disposed on the substrate in the peripheral area along an edge of the substrate in a plan view, where the first blocking structure blocks crack propagation; a second blocking structure disposed on the substrate in the peripheral area between the display area and the first blocking structure in the plan view, where the second blocking structure blocks moisture; and a crack detection structure disposed on the substrate in the peripheral area between the display area and the second blocking structure in the plan view, where the crack detection structure includes a lower line layer disposed on the substrate, a middle line layer which is disposed on the lower line layer and includes a crack detection line, and an upper line layer disposed on the middle line layer.

In an embodiment, the crack detection structure may be spaced apart from the first blocking structure and the second blocking structure.

In an embodiment, the second blocking structure may surround the crack detection structure in the plan view, and the first blocking structure may surround the second blocking structure in the plan view.

In an embodiment, the display device may further include a crack detection circuit disposed on the substrate in the peripheral area. In such an embodiment, the crack detection line may include a first crack detection line which receives a test voltage and a second crack detection line, where a first end of the second crack detection line is electrically connected to the first crack detection line and a second end of the second crack detection line, which is opposite to the first end, is electrically connected to the crack detection circuit.

In an embodiment, the second crack detection line may be disposed on the first crack detection line.

In an embodiment, the crack detection structure may include first to eighth line layers sequentially stacked on the substrate. In such an embodiment, the lower line layer may include the first to fourth line layers, the middle line layer may include the fifth line layer and the sixth line layer, and the upper line layer may include the seventh line layer and the eighth line layer.

In an embodiment, the first crack detection line may be disposed in a same layer as the fifth line layer, and the second crack detection line may be disposed in a same layer as the sixth line layer.

In an embodiment, the substrate may include a silicon wafer.

A display device according to an embodiment of the disclosure includes: a substrate including a display area and a peripheral area surrounding the display area; a plurality of sub-pixels disposed on the substrate in the display area; a blocking structure disposed on the substrate in the peripheral area along an edge of the substrate to surrounding the display area in a plan view; a crack detection structure disposed on the substrate in the peripheral area between the display area and the blocking structure in the plan view, where the crack detection structure includes a lower line layer disposed on the substrate, a middle line layer which is disposed on the lower line layer and includes a crack detection line, and an upper line layer disposed on the middle line layer; a plurality of pads disposed in the peripheral area on the substrate and adjacent to the edge of the substrate in the plan view; a crack detection circuit disposed on the substrate in the peripheral area between the display area and the plurality of pads in the plan view, and electrically connected to the crack detection line; and a demux portion disposed on the substrate in the peripheral area between the display area and the crack detection circuit in the plan view.

In an embodiment, the crack detection structure may be spaced apart from the blocking structure in the plan view.

In an embodiment, the blocking structure may surround the crack detection structure in the plan view.

In an embodiment, the crack detection line may include a first crack detection line which receives a test voltage and a second crack detection line, where a first end of the second crack detection line is electrically connected to the first crack detection line, and a second end of the second crack detection line, which is opposite to the first end, is electrically connected to the crack detection circuit.

In an embodiment, at least one of the plurality of pads may provide the test voltage to the first crack detection line.

In an embodiment, the second crack detection line may be disposed on the first crack detection line.

In an embodiment, the display device may further include a plurality of fan out lines disposed on the substrate and disposed in the peripheral area at a lower side of the demux portion in the plan view and a plurality of data lines disposed on the substrate and disposed in the display area and connected to the plurality of sub-pixels.

In an embodiment, the crack detection circuit may include a constant voltage line to which the test voltage is applied and a detection switch connected to each of the plurality of fan out lines.

In an embodiment, at least one of the plurality of fan out lines may be electrically connected to the constant voltage line through the detection switch, and at least another one of the plurality of fan out lines may be electrically connected to the second crack detection line through the detection switch.

In an embodiment, the crack detection structure may include first to eighth line layers sequentially stacked on the substrate. In such an embodiment, the lower line layer may include the first to fourth line layers. In such an embodiment, the middle line layer may include the fifth line layer and the sixth line layer. In such an embodiment, the upper line layer may include the seventh line layer and the eighth line layer. In such an embodiment, the first crack detection line may be disposed in a same layer as the fifth line layer, and the second crack detection line may be disposed in a same layer as the sixth line layer.

In an embodiment, the display device may further include a driving chip disposed on the substrate in the peripheral area and connected to the plurality of pads. In such an embodiment, the crack detection circuit may be disposed between the demux portion and the driving chip in the plan view.

An electronic device according to an embodiment of the disclosure includes: a display device including a plurality of sub-pixels; and a processor which provides an image data signal and an input control signal to the display device. In such an embodiment, the display device includes: a substrate including a display area and a peripheral area surrounding the display area; the plurality of sub-pixels disposed on the substrate in the display area; a first blocking structure disposed on the substrate in the peripheral area along an edge of the substrate in a plan view, where the first blocking structure blocks crack propagation; a second blocking structure disposed on the substrate in the peripheral area on between the display area and the first blocking structure in the plan view, where the second blocking structure blocks moisture; and a crack detection structure disposed on the substrate in the peripheral area between the display area and the second blocking structure in the plan view, where the crack detection structure includes a lower line layer disposed on the substrate, a middle line layer which is disposed on the lower line layer and includes a crack detection line, and an upper line layer disposed on the middle line layer.

A display device according to embodiments of the disclosure may include a substrate including a display area and a peripheral area surrounding the display area, a blocking structure disposed on the substrate in the peripheral area disposed along an edge of the substrate to surround the display area in a plan view, and a crack detection structure disposed on the substrate in the peripheral area between the display area and the blocking structure in a plan view. In such embodiments, the crack detection structure may include a lower line layer disposed on the substrate, a middle line layer which is disposed on the lower line layer and includes a crack detection line, and an upper line layer disposed on the middle line layer.

In such embodiments, the blocking structure may block cracks from propagating toward the display area during sawing and packaging processes of a wafer. In addition, the blocking structure may block moisture from penetrating toward the display area through a scribing line during a back grinding process of the wafer.

In such embodiments, the crack detection line may be disposed in the middle line layer of the crack detection structure. Accordingly, compared to a case where the crack detection line is disposed in the lower line layer or the upper line layer of the crack detection structure, the crack detection structure may detect cracks that are not blocked by the blocking structure with appropriate or desired crack detection sensitivity.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the disclosure.

FIG. 2 is a view illustrating a crack detection circuit included in the display device of FIG. 1.

FIG. 3 is an enlarged plan view of area A of FIG. 1.

FIG. 4 is a cross-sectional view taken along line II-II′ of FIG. 3.

FIG. 5 is a cross-sectional view taken along line I-I′ of FIG. 1.

FIG. 6 is an enlarged plan view of area B of FIG. 1.

FIG. 7 is a cross-sectional view illustrating a first blocking structure, a second blocking structure, and a crack detection structure included in the display device of FIG. 1.

FIGS. 8, 9, 10, and 11 are views illustrating an embodiment of a method of manufacturing the display device of FIG. 1.

FIG. 12 is a block diagram of an electronic device according to an embodiment of the disclosure.

FIG. 13 is a schematic diagram of an electronic device according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings. The same reference numerals are used for the same components in the drawings, and any repetitive detailed descriptions of the same components will be omitted.

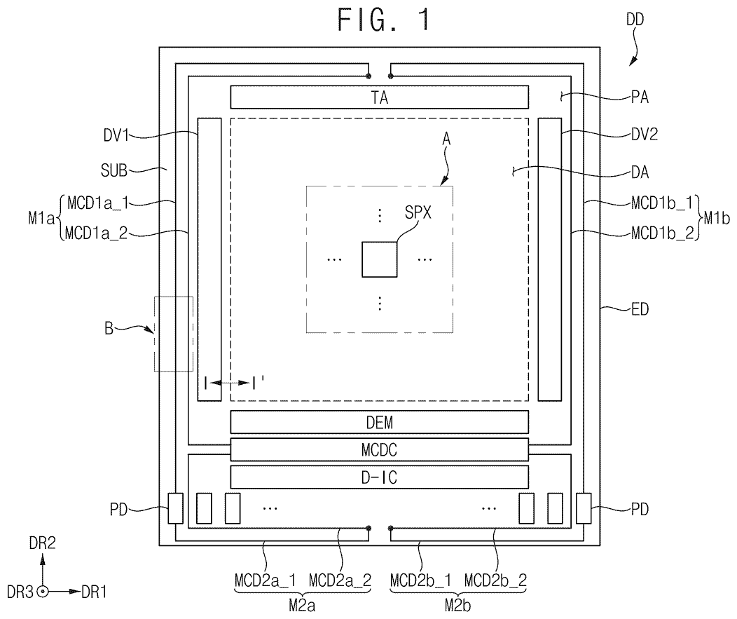

FIG. 1 is a plan view illustrating a display device according to an embodiment of the disclosure.

In the disclosure, a plane may be defined by a first direction DR1 and a second direction DR2 intersecting the first direction DR1. For example, the first direction DR1 and the second direction DR2 may be perpendicular to each other. A direction normal to the plane, that is, a thickness direction of a display device DD may be a third direction DR3. In other words, the third direction DR3 may be perpendicular to each of the first direction DR1 and the second direction DR2. As used herein, the “plan view” is a view in the third direction DR3.

Referring to FIG. 1, the display device DD according to an embodiment of the disclosure may include a substrate SUB, pads PD, a driving chip D-IC, a crack detection circuit MCDC, first crack detection portions M1a and M1b, second crack detection portions M2a and M2b, a demux portion DEM, a first gate driver DV1, a second gate driver DV2, a test array TA, and sub-pixels SPX.

The display device DD may have a rectangular planar shape. In an embodiment, for example, the display device DD may have a substantially rectangular planar shape with a short side extending in the first direction DR1 and a long side extending in the second direction DR2. However, the disclosure is not limited thereto, and the planar shape of the display device DD may be variously changed according to embodiments.

The substrate SUB may have an edge ED including a first side, a second side, a third side, and a fourth side. The first side of the substrate SUB may extend in the first direction DR1. The second side of the substrate SUB may contact the first side and extend in the second direction DR2. The third side of the substrate SUB may contact the second side and extend parallel to and opposing the first side. The fourth side of the substrate SUB may contact the first side and the third side, and may extend parallel to and opposing the second side.

The substrate SUB may include a display area DA and a peripheral area PA. The display area DA may be defined as an area that displays an image by generating light or adjusting the transmittance of light provided from an external light source. The sub-pixels SPX may be arranged (or disposed) in the display area DA. Each of the sub-pixels SPX may be defined as a minimum light-emitting unit capable of displaying light of various colors. Each of the sub-pixels SPX may generate light based on a driving signal. In an embodiment, for example, the sub-pixels SPX may be arranged in a matrix form along the first direction DR1 and the second direction DR2.

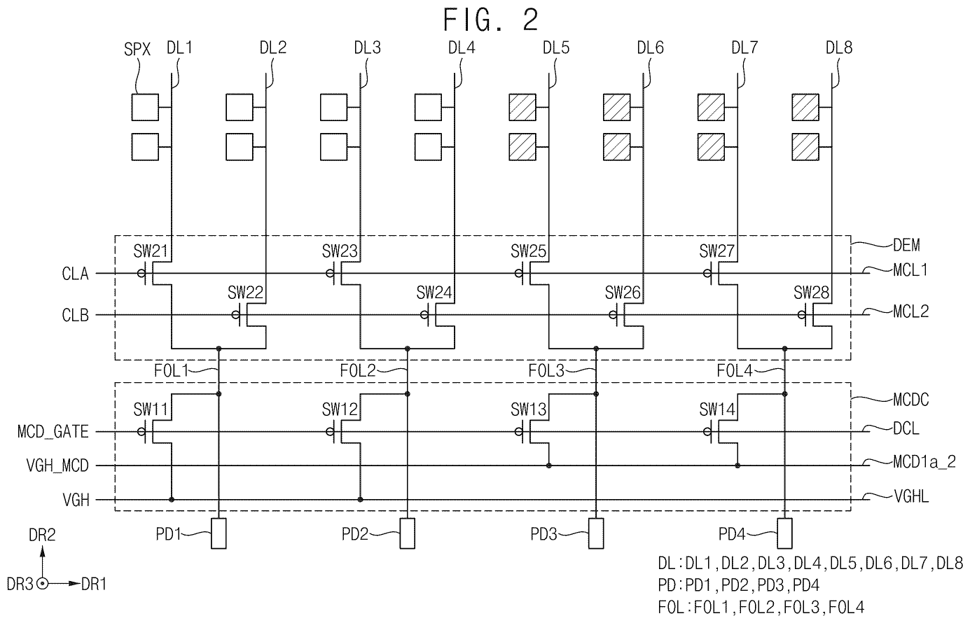

The lines that are connected to the sub-pixels SPX may be arranged in the display area DA. In an embodiment, for example, the lines may include data lines (DL, refer to FIG. 2) connected to the sub-pixels SPX to provide a data voltage, gate lines connected to the sub-pixels SPX to provide a gate signal, or the like. Each of the data lines may extend in the second direction DR2, and each of the gate lines may extend in the first direction DR1.

The peripheral area PA may be located around the display area DA. The peripheral area PA may surround at least a portion of the display area DA in a plan view (or when viewed in the third direction DR3). In an embodiment, for example, the peripheral area PA may entirely surround the display area DA in a plan view. The peripheral area PA may not display an image.

The test array TA may be arranged in the peripheral area PA on the substrate SUB. In an embodiment, for example, the test array TA may be arranged in the peripheral area PA adjacent to an upper side of the display area DA. The test array TA may include test elements for testing characteristics of the display device DD. In an embodiment, for example, the test array TA may include a test element for testing a characteristic of a transistor, a test element for measuring a surface resistance of a semiconductor layer included in the transistor, or the like. However, the disclosure is not limited thereto.

The first gate driver DV1 and the second gate driver DV2 may be arranged in the peripheral area PA on the substrate SUB. In an embodiment, for example, the first gate driver DV1 may be arranged in the peripheral area PA adjacent to a left side of the display area DA, and the second gate driver DV2 may be arranged in the peripheral area PA adjacent to a right side of the display area DA. The first gate driver DV1 and the second gate driver DV2 may provide the gate signal to the sub-pixels SPX through the gate lines. In an embodiment, one of the first gate driver DV1 and the second gate driver DV2 may be omitted.

The demux portion DEM may be arranged in the peripheral area PA on the substrate SUB. In an embodiment, for example, the demux portion DEM may be arranged in the peripheral area PA adjacent to a lower side of the display area DA. In an embodiment, the demux portion DEM may be arranged between the display area DA and the crack detection circuit MCDC in a plan view.

In an embodiment, the demux portion DEM may include a first demux control line (MCL1, refer to FIG. 2), a second demux control line (MCL2, refer to FIG. 2), and demux switches. A plurality of fan out lines (FOL, refer to FIG. 2) may be arranged on a lower side of the demux portion DEM, and the demux portion DEM may connect one fan out line and multiple data lines through the demux switches. A detailed features thereof will be described below with reference to FIG. 2.

The driving chip D-IC and the pads PD may be arranged in the peripheral area PA on the substrate SUB. In an embodiment, the driving chip D-IC and the pads PD may be arranged on a lower side of the crack detection circuit MCDC in a plan view. The driving chip D-IC and the pads PD may be adjacent to the edge ED of the substrate SUB in a plan view. The driving chip D-IC may be connected to the pads PD through an anisotropic conductive film. The driving chip D-IC may provide the driving signal to the sub-pixels SPX. The driving signal may include various signals to drive the sub-pixels SPX, such as a driving voltage, a data voltage, or the like. The driving signal may be transmitted to the sub-pixels SPX through the pads PD. In an embodiment, for example, the driving chip D-IC may be a data driver.

The first crack detection portions M1a and M1b may be arranged in the peripheral area PA on the substrate SUB. The first crack detection portions M1a, M1b may include a first first crack detection portion (hereinafter, will be referred to as “(1-1)-th crack detection portion”) M1a and a second first crack detection portion (hereinafter, will be referred to as “(1-2)-th crack detection portion”) M1b. The (1-1)-th crack detection portion M1a may be arranged in the peripheral area PA adjacent to the left side and the upper side of the display area DA. The (1-2)-th crack detection portion M1b may be arranged in the peripheral area PA adjacent to the right side and the upper side of the display area DA.

Each of the first crack detection portions M1a and M1b may include a first crack detection line MCD1a_1 (or MCD1b_1) and a second crack detection line MCD1a_2 (or MCD1b_2). A first end of the first crack detection line MCD1a_1 (or MCD1b_1) may be electrically connected to the pad PD. The first crack detection line MCD1a_1 (or MCD1b_1) may receive a test voltage (VGH, refer to FIG. 2) through the pad PD. A second end, which is opposite to the first end, of the first crack detection line MCD1a_1 (or MCD1b_1) may be electrically connected to a first end of the second crack detection line MCD1a_2 (or MCD1b_2). The second end, which is opposite to the first end, of the second crack detection line MCD1a_2 (or MCD1b_2) may be electrically connected to the crack detection circuit MCDC.

At least a portion of each of the first crack detection line MCD1a_1 (or MCD1b_1) and the second crack detection line MCD1a_2 (or MCD1b_2) may extend in parallel with each other along the edge ED of the substrate SUB. In an embodiment, for example, the second crack detection line MCD1a_2 (or MCD1b_2) arranged in the peripheral area PA adjacent to the left side and the right side of the display area DA may be located between the first crack detection line MCD1a_1 (or MCD1b_1) and the gate driver DV1 (or DV2) in a plan view.

The second crack detection portions M2a and M2b may be arranged in the peripheral area PA on the substrate SUB. The second crack detection portions M2a and M2b may include a first second crack detection portion (hereinafter, will be referred to as “(2-1)-th crack detection portion”) M2a and a second second crack detection portion (hereinafter, will be referred to as “(2-2)-th crack detection portion”) M2b. The (2-1)-th crack detection portion M2a may be arranged in the peripheral area PA adjacent to the left side and the lower side of the display area DA. The (2-2)-th crack detection portion M2b may be arranged in the peripheral area PA adjacent to the right side and the lower side of the display area DA.

Each of the second crack detection portions M2a and M2b may include a first crack detection line MCD2a_1 (or MCD2b_1) and a second crack detection line MCD2a_2 (or MCD2b_2). A first end of the first crack detection line MCD2a_1 (or MCD2b_1) may be electrically connected to the pad PD. The first crack detection line MCD2a_1 (or MCD2b_1) may receive a test voltage (VGH, refer to FIG. 2) through the pad PD. The second end, which is opposite to the first end, of the first crack detection line MCD2a_1 (or MCD2b_1) may be electrically connected to a first end of the second crack detection line MCD2a_2 (or MCD2b_2). The second end, which is opposite to the first end, of the second crack detection line MCD2a_2 (or MCD2b_2) may be electrically connected to the crack detection circuit MCDC.

At least a portion of each of the first crack detection line MCD2a_1 (or MCD2b_1) and the second crack detection line MCD2a_2 (or MCD2b_2) may extend in parallel with each other along the edge ED of the substrate SUB. In an embodiment, for example, the second crack detection line MCD2a_2 (or MCD2b_2) arranged in the peripheral area PA adjacent to the lower side of the display area DA may be located between the first crack detection line MCD2a_1 (or MCD2b_1) and the driving chip D-IC in a plan view.

The crack detection circuit MCDC may be arranged in the peripheral area PA on the substrate SUB. The crack detection circuit MCDC may be arranged between the display area DA and the pads PD in a plan view. In an embodiment, the crack detection circuit MCDC may be arranged between the demux portion DEM and the pads PD in a plan view. In addition, the crack detection circuit MCDC may be arranged between the demux portion DEM and the driving chip D-IC in a plan view. The crack detection circuit MCDC may include detection switches. The crack detection circuit MCDC may inspect (or detect) crack defects occurring in the peripheral area PA of the substrate SUB.

In an embodiment, for example, the first crack detection portions M1a and M1b and the crack detection circuit MCDC may inspect (or detect) crack defects occurring in the peripheral area PA adjacent to the upper side, the left side, and the right side of the display area DA. The second crack detection portions M2a and M2b and the crack detection circuit MCDC may inspect crack defects occurring in the peripheral area PA adjacent to the lower side, the left side, and the right side of the display area DA. In an embodiment, the second crack detection portions M2a and M2b and the crack detection circuit MCDC may inspect crack defects occurring in the peripheral area PA adjacent to the driving chip D-IC.

The first crack detection portions M1a and M1b and the second crack detection portions M2a and M2b may differ in an area for inspecting the crack defects, but the method for inspecting the crack defects may be substantially the same in the first crack detection portions M1a and M1b and the second crack detection portions M2a and M2b. Therefore, the description of the first crack detection portions M1a and M1b may be substantially equally applicable to the second crack detection portions M2a and M2b. In addition, the (1-1)-th crack detection portion M1a and the (1-2)-th crack detection portion M1b may have substantially the same or symmetrical shapes as each other. Therefore, the following description will focus on the (1-1)-th crack detection portion M1a. The description of the (1-1)-th crack detection portion M1a may be substantially equally applicable to the (1-2)-th crack detection portion M1b.

In an embodiment, for example, the display device DD may be a display device such as an organic light-emitting diode display device, a liquid crystal display device, an organic light emitting diode on silicon (OLEDoS), a liquid crystal on silicon (LCoS), or a light emitting diode on silicon (LEDoS). In an embodiment, the display device DD may be a display device such as an OLEDoS.

In an embodiment where the display device DD is a display device such as an OLEDoS, the display device DD may configure a head-mounted display, which is a glasses-type monitor device for virtual reality or augmented reality that is worn in the form of glasses, a helmet, or the like and has a focus formed at a close distance in front of a user's eyes. However, the disclosure is not limited thereto, and the display device DD may configure various displays.

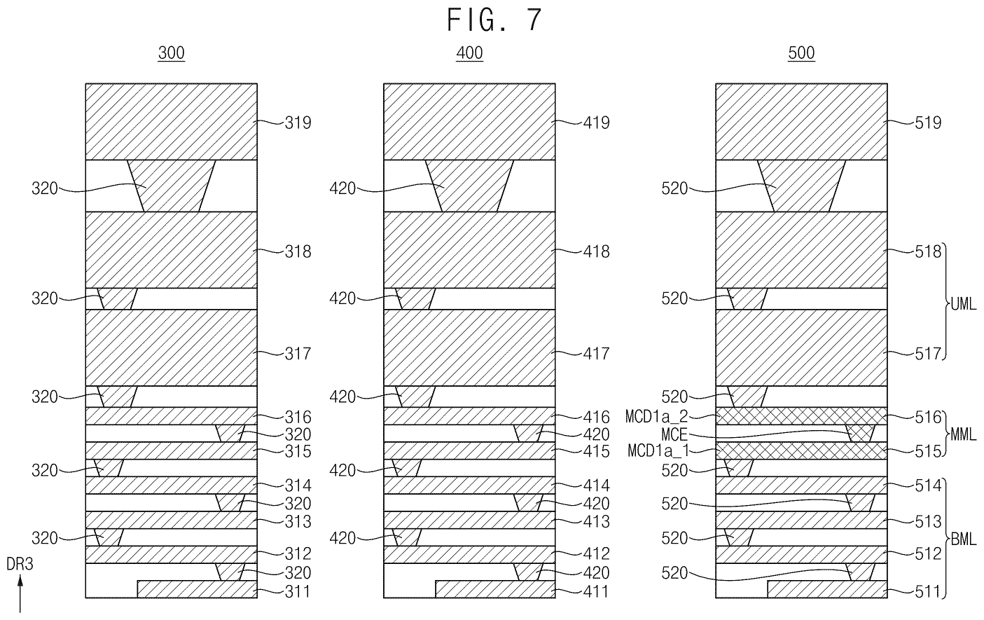

The display device DD may further include a first blocking structure (300, refer to FIG. 6) arranged on the substrate SUB and arranged along the edge ED of the substrate SUB in a plan view and a second blocking structure (400, refer to FIG. 6) arranged on the substrate SUB and arranged between the first blocking structure 300 and the first crack detection lines MCD1a_1, MCD1b_1, MCD2a_1, and MCD2b_1 in a plan view. A detailed features thereof will be described below with reference to FIGS. 6 and 7.

FIG. 2 is a view illustrating a crack detection circuit included in the display device of FIG. 1.

Referring to FIGS. 1 and 2, an embodiment of the display device DD may include the crack detection circuit MCDC, fan out lines FOL, the demux portion DEM, data lines DL, the sub-pixels SPX, and the pads PD. The data lines DL may include first to eighth data lines DL1, DL2, DL3, DL4, DL5, DL6, DL7, and DL8. In FIG. 2, for convenience of illustration and description, only some of the sub-pixels SPX arranged in the display area DA are illustrated, and only the first to eighth data lines DL1, DL2, DL3, DL4, DL5, DL6, DL7, and DL8 connected to the sub-pixels SPX are illustrated.

The pads PD may be arranged in the peripheral area PA on the substrate SUB. The pads PD may be connected to the driving chip D-IC. The pads PD may receive various voltages from the driving chip D-IC. In an embodiment, for example, the pads PD may include first to fourth pads PD1, PD2, PD3, and PD4.

The fan out lines FOL may be arranged between the demux portion DEM and the pads PD in a plan view. The fan out lines FOL may be repeatedly arranged along the first direction DR1. Each of the fan out lines FOL may extend in the second direction DR2. In an embodiment, for example, the fan out lines FOL may include first to fourth fan out lines FOL1, FOL2, FOL3, and FOL4.

A first end of the first fan out line FOL1 may be electrically connected to the first pad PD1, and a second end, which is opposite to the first end, of the first fan out line FOL1 may be electrically connected to the first data line DL1 and the second data line DL2. A first end of the second fan out line FOL2 may be electrically connected to the second pad PD2, and a second end, which is opposite to the first end, of the second fan out line FOL2 may be electrically connected to the third data line DL3 and the fourth data line DL4. A first end of the third fan out line FOL3 may be electrically connected to the third pad PD3, and a second end, which is opposite to the first end, of the third fan out line FOL3 may be electrically connected to the fifth data line DL5 and the sixth data line DL6. A first end of the fourth fan out line FOL4 may be electrically connected to the fourth pad PD4, and a second end, which is opposite to the first end, of the fourth fan out line FOL4 may be electrically connected to the seventh data line DL7 and the eighth data line DL8.

The crack detection circuit MCDC may be arranged between the pads PD and the demux portion DEM in a plan view. The crack detection circuit MCDC may include a constant voltage line VGHL, the second crack detection line MCD1a_2, a detection control line DCL, and detection switches. In an embodiment, for example, the detection switches may include a first detection switch SW11, a second detection switch SW12, a third detection switch SW13, and a fourth detection switch SW14.

The constant voltage line VGHL, the second crack detection line MCD1a_2, and the detection control line DCL may be spaced apart from each other in the second direction DR2. Each of the constant voltage line VGHL, the second crack detection line MCD1_2, and the detection control line DCL may extend in the first direction DR1.

The first detection switch SW11 may include a first terminal, a second terminal, and a gate terminal. The gate terminal of the first detection switch SW11 may receive a detection control signal MCD_GATE through the detection control line DCL. The first terminal of the first detection switch SW11 may be connected to the constant voltage line VGHL. The second terminal of the first detection switch SW11 may be connected to the first fan out line FOL1. When the first detection switch SW11 is turned on in response to the detection control signal MCD_GATE, the first detection switch SW11 may connect the constant voltage line VGHL and the first fan out line FOL1 to each other.

The second detection switch SW12 may include a first terminal, a second terminal, and a gate terminal. The gate terminal of the second detection switch SW12 may receive the detection control signal MCD_GATE through the detection control line DCL. The first terminal of the second detection switch SW12 may be connected to the constant voltage line VGHL. The second terminal of the second detection switch SW12 may be connected to the second fan out line FOL2. When the second detection switch SW12 is turned on in response to the detection control signal MCD_GATE, the second detection switch SW12 may connect the constant voltage line VGHL and the second fan out line FOL2 to each other.

The third detection switch SW13 may include a first terminal, a second terminal, and a gate terminal. The gate terminal of the third detection switch SW13 may receive the detection control signal MCD_GATE through the detection control line DCL. The first terminal of the third detection switch SW13 may be connected to the second crack detection line MCD1a_2. The second terminal of the third detection switch SW13 may be connected to the third fan out line FOL3. When the third detection switch SW13 is turned on in response to the detection control signal MCD_GATE, the third detection switch SW13 may connect the second crack detection line MCD1a_2 and the third fan out line FOL3 to each other.

The fourth detection switch SW14 may include a first terminal, a second terminal, and a gate terminal. The gate terminal of the fourth detection switch SW14 may receive the detection control signal MCD_GATE through the detection control line DCL. The first terminal of the fourth detection switch SW14 may be connected to the second crack detection line MCD1a_2. The second terminal of the fourth detection switch SW14 may be connected to the fourth fan out line FOL4. When the fourth detection switch SW14 is turned on in response to the detection control signal MCD_GATE, the fourth detection switch SW14 may connect the second crack detection line MCD1a_2 and the fourth fan out line FOL4 to each other.

The demux portion DEM may be arranged between the sub-pixels SPX and the crack detection circuit MCDC in a plan view. The demux portion DEM may include a first demux control line MCL1, a second demux control line MCL2, and demux switches. The demux portion DEM may connect one fan out line FOL to multiple data lines DL through the demux switches. In an embodiment, for example, the demux switches may include first to eighth demux switches SW21, SW22, SW23, SW24, SW25, SW26, SW27, and SW28.

The first demux control line MCL1 and the second demux control line MCL2 may be spaced apart from each other in the second direction DR2. Each of the first demux control line MCL1 and the second demux control line MCL2 may extend in the first direction DR1.

The first demux switch SW21 may include a first terminal, a second terminal, and a gate terminal. The gate terminal of the first demux switch SW21 may receive a first demux control signal CLA through the first demux control line MCL1. The first terminal of the first demux switch SW21 may be connected to the first fan out line FOL1. The second terminal of the first demux switch SW21 may be connected to the first data line DL1. When the first demux switch SW21 is turned on in response to the first demux control signal CLA, the first demux switch SW21 may connect the first fan out line FOL1 and the first data line DL1 to each other.

The second demux switch SW22 may include a first terminal, a second terminal, and a gate terminal. The gate terminal of the second demux switch SW22 may receive a second demux control signal CLB through the second demux control line MCL2. The first terminal of the second demux switch SW22 may be connected to the first fan out line FOL1. The second terminal of the second demux switch SW22 may be connected to the second data line DL2. When the second demux switch SW22 is turned on in response to the second demux control signal CLB, the second demux switch SW22 may connect the first fan out line FOL1 and the second data line DL2 to each other.

The third demux switch SW23 may include a first terminal, a second terminal, and a gate terminal. The gate terminal of the third demux switch SW23 may receive the first demux control signal CLA through the first demux control line MCL1. The first terminal of the third demux switch SW23 may be connected to the second fan out line FOL2. The second terminal of the third demux switch SW23 may be connected to the third data line DL3. When the third demux switch SW23 is turned on in response to the first demux control signal CLA, the third demux switch SW23 may connect the second fan out line FOL2 and the third data line DL3 to each other.

The fourth demux switch SW24 may include a first terminal, a second terminal, and a gate terminal. The gate terminal of the fourth demux switch SW24 may receive the second demux control signal CLB through the second demux control line MCL2. The first terminal of the fourth demux switch SW24 may be connected to the second fan out line FOL2. The second terminal of the fourth demux switch SW24 may be connected to the fourth data line DL4. When the fourth demux switch SW24 is turned on in response to the second demux control signal CLB, the fourth demux switch SW24 may connect the second fan out line FOL2 and the fourth data line DL4 to each other.

The fifth demux switch SW25 may include a first terminal, a second terminal, and a gate terminal. The gate terminal of the fifth demux switch SW25 may receive the first demux control signal CLA through the first demux control line MCL1. The first terminal of the fifth demux switch SW25 may be connected to the third fan out line FOL3. The second terminal of the fifth demux switch SW25 may be connected to the fifth data line DL5. When the fifth demux switch SW25 is turned on in response to the first demux control signal CLA, the fifth demux switch SW25 may connect the third fan out line FOL3 and the fifth data line DL5 to each other.

The sixth demux switch SW26 may include a first terminal, a second terminal, and a gate terminal. The gate terminal of the sixth demux switch SW26 may receive the second demux control signal CLB through the second demux control line MCL2. The first terminal of the sixth demux switch SW26 may be connected to the third fan out line FOL3. The second terminal of the sixth demux switch SW26 may be connected to the sixth data line DL6. When the sixth demux switch SW26 is turned on in response to the second demux control signal CLB, the sixth demux switch SW26 may connect the third fan out line FOL3 and the sixth data line DL6 to each other.

The seventh demux switch SW27 may include a first terminal, a second terminal, and a gate terminal. The gate terminal of the seventh demux switch SW27 may receive the first demux control signal CLA through the first demux control line MCL1. The first terminal of the seventh demux switch SW27 may be connected to the fourth fan out line FOL4. The second terminal of the seventh demux switch SW27 may be connected to the seventh data line DL7. When the seventh demux switch SW27 is turned on in response to the first demux control signal CLA, the seventh demux switch SW27 may connect the fourth fan out line FOL4 and the seventh data line DL7 to each other.

The eighth demux switch SW28 may include a first terminal, a second terminal, and a gate terminal. The gate terminal of the eighth demux switch SW28 may be receive the second demux control signal CLB through the second demux control line MCL2. The first terminal of the eighth demux switch SW28 may be connected to the fourth fan out line FOL4. The second terminal of the eighth demux switch SW28 may be connected to the eighth data line DL8. When the eighth demux switch SW28 is turned on in response to the second demux control signal CLB, the eighth demux switch SW28 may connect the fourth fan out line FOL4 and the eighth data line DL8 to each other.

In FIG. 2, an embodiment where two demux switches are arranged corresponding to one fan out line FOL is illustrated as an example, but the disclosure is not limited thereto. In another embodiment, for example, three or more demux switches may be arranged in response to one fan out line FOL. In such an embodiment, one fan out line FOL may be connected to three or more data lines DL.

When the display device DD is driven in a detection mode, the test voltage VGH may be applied to the first crack detection line MCD1a_1. When no cracks occurs in the peripheral area PA of the substrate SUB, a magnitude of a voltage of the second crack detection line MCD1a_2 that has passed through (or via) the peripheral area PA may be constant. In contrast, when a crack occurs in the peripheral area PA of the substrate SUB, a magnitude of a voltage of the second crack detection line MCD1a_2 that has passed through (or via) the peripheral area PA may be reduced.

When the display device DD is driven in the detection mode, the crack detection circuit MCDC may be activated. In an embodiment, for example, the detection control signal MCD_GATE having a low voltage level may be applied to the gate terminals of the first to fourth detection switches SW11, SW12, SW13, and SW14, and the first to fourth detection switches SW11, SW12, SW13, and SW14 may be turned on. Accordingly, some of the fan out lines FOL may be electrically connected to the constant voltage line VGHL through the detection switches, and other some of the fan out lines FOL may be electrically connected to the second crack detection line MCD1a_2 through the detection switches. In an embodiment, for example, the first fan out line FOL1 and the second fan out line FOL2 may be electrically connected to the constant voltage line VGHL through the first detection switch SW11 and the second detection switch SW12, respectively. In an embodiment, for example, the third fan out line FOL3 and the fourth fan out line FOL4 may be electrically connected to the second crack detection line MCD1a_2 through the third detection switch SW13 and the fourth detection switch SW14, respectively.

In addition, when the display device DD is driven in the detection mode, the demux portion DEM may be activated. In an embodiment, for example, the first demux control signal CLA having a low voltage level may be applied to the gate terminals of the first demux switch SW21, the third demux switch SW23, the fifth demux switch SW25, and the seventh demux switch SW27, and the second demux control signal CLB having a low voltage level may be applied to the gate terminals of the second demux switch SW22, the fourth demux switch SW24, the sixth demux switch SW26, and the eighth demux switch SW28. Accordingly, the first to eighth demux switches SW21, SW22, SW23, SW24, SW25, SW26, SW27, and SW28 may be turned on. As a result, the first fan out line FOL1 may be electrically connected to the first data line DL1 and the second data line DL2, the second fan out line FOL2 may be electrically connected to the third data line DL3 and the fourth data line DL4, the third fan out line FOL3 may be electrically connected to the fifth data line DL5 and the sixth data line DL6, and the fourth fan out line FOL4 may be electrically connected to the seventh data line DL7 and the eighth data line DL8.

When the display device DD is driven in the detection mode, the test voltage VGH may be applied to the constant voltage line VGHL. Accordingly, the test voltage VGH may be applied to the first data line DL1 and the second data line DL2 through the first fan out line FOL1. In addition, the test voltage VGH may be applied to the third data line DL3 and the fourth data line DL4 through the second fan out line FOL2. Accordingly, the sub-pixels SPX connected to the first to fourth data lines DL1, DL2, DL3, and DL4 may emit red light, green light, or blue light. However, the disclosure is not limited thereto.

When a crack occurs in the peripheral area PA of the substrate SUB, a first voltage VGH_MCD smaller than the test voltage VGH may be applied to the second crack detection line MCD1a_2 that has passed through the peripheral area PA. The first voltage VGH_MCD may be applied to the fifth data line DL5 and the sixth data line DL6 through the third fan out line FOL3. In addition, the first voltage VGH_MCD may be applied to the seventh data line DL7 and the eighth data line DL8 through the fourth fan out line FOL4. In an embodiment, for example, when the first voltage VGH_MCD smaller than the test voltage VGH is applied to the fifth to eighth data lines DL5, DL6, DL7, and DL8, the sub-pixels SPX connected to the fifth to eighth data lines DL5, DL6, DL7, and DL8 may display black color. Through this, a crack defect that has occurred in the peripheral area PA of the substrate SUB may be detected.

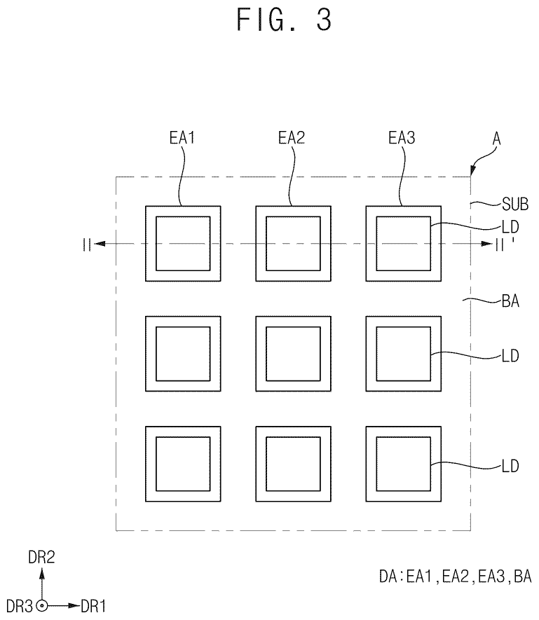

FIG. 3 is an enlarged plan view of area A of FIG. 1. Particularly, FIG. 3 is an enlarged plan view of a portion of the display area DA.

Referring to FIG. 3, an embodiment of the display device DD may include the display area DA, and the display area DA may include a first light-emitting area EA1, a second light-emitting area EA2, a third light-emitting area EA3, and a light blocking area BA.

In an embodiment, for example, each of the first to third light-emitting areas EA1, EA2 and EA3 may have a rectangular planar shape. However, the disclosure is not limited thereto, and each of the first to third light-emitting areas EA1, EA2, and EA3 may have any one of a triangular planar shape, a circular planar shape, and an elliptical planar shape.

In an embodiment, for example, the first to third light-emitting areas EA1, EA2, and EA3 may have a same size and/or shape as each other. However, the disclosure is not limited thereto, and the first to third light-emitting areas EA1, EA2, and EA3 may have different sizes.

Each of the first to third light-emitting areas EA1, EA2, and EA3 may include a light-emitting element LD that emits first light. In an embodiment, for example, the first light may be white light. However, the disclosure is not limited thereto, and the light-emitting element LD included in the first light-emitting area EA1 may emit red light, the light-emitting element LD included in the second light-emitting area EA2 may emit green light, and the light-emitting element LD included in the third light-emitting area EA3 may emit blue light. In an embodiment, the light-emitting element LD may be a micro organic light-emitting diode. However, the disclosure is not limited thereto.

The first light-emitting area EA1 may emit second light. The first light-emitting area EA1 may convert the first light emitted from the light-emitting element LD into the second light and may emit the second light. In an embodiment, for example, the second light may be red light, but the disclosure is not limited thereto.

The second light-emitting area EA2 may emit third light. The second light-emitting area EA2 may convert the first light emitted from the light-emitting element LD into the third light and may emit the third light. In an embodiment, for example, the third light may be green light, but the disclosure is not limited thereto.

The third light-emitting area EA3 may emit fourth light. The third light-emitting area EA3 may convert the first light emitted from the light-emitting element LD into the fourth light and may emit the fourth light. In an embodiment, for example, the fourth light may be blue light, but the disclosure is not limited thereto.

In an embodiment, for example, the first light-emitting area EA1, the second light-emitting area EA2, and the third light-emitting area EA3 may be sequentially arranged along the first direction DR1. In addition, the first light-emitting area EA1, the second light-emitting area EA2, and the third light-emitting area EA3 may be sequentially arranged along a opposite direction of the second direction DR2. However, the arrangement structure of the first to third light-emitting areas EA1, EA2, and EA3 is not limited thereto.

The light blocking area BA may be arranged between the first to third light-emitting areas EA1, EA2, and EA3. In an embodiment, for example, the light blocking area BA may surround the first to third light-emitting areas EA1, EA2, and EA3 in a plan view. In an embodiment, for example, the light blocking area BA may have a mesh shape, a net shape, a lattice shape, or the like in a plan view. The light blocking area BA may be defined as an area that blocks light.

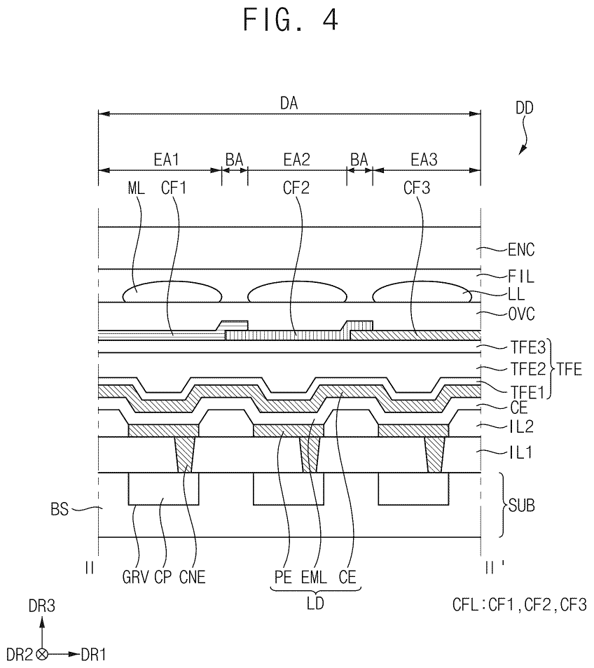

FIG. 4 is a cross-sectional view taken along line II-II′ of FIG. 3.

Referring to FIG. 4, an embodiment of the display device DD may include the substrate SUB, a first insulating layer IL1, a connection electrode CNE, a second insulating layer IL2, the light-emitting elements LD, an encapsulation layer TFE, a color filter layer CFL, a flattening layer OVC, a lens layer LL, a filling layer FIL, and an encapsulation substrate ENC in the display area DA. Each of the light-emitting elements LD may include a pixel electrode PE, a light-emitting layer EML, and a common electrode CE.

The substrate SUB may include a base substrate BS and a plurality of pixel driving circuits CP. The substrate SUB may be a semiconductor circuit board. In an embodiment, the substrate SUB may include a silicon wafer. However, the disclosure is not limited thereto, and the substrate SUB may be a gallium arsenide substrate, a ceramic substrate, a quartz substrate, or a semiconductor on insulator (SOI) substrate.

Grooves GRV may be defined in the base substrate BS. The pixel driving circuits CP may be accommodated in the grooves GRV, respectively. Each of the pixel driving circuits CP may include at least one transistor and at least one capacitor.

The first insulating layer IL1 may be arranged on the substrate SUB. The first insulating layer IL1 may define a contact hole that exposes a portion of the pixel driving circuit CP. The first insulating layer IL1 may include an inorganic insulating material and/or an organic insulating material. Examples of the inorganic insulating material that may be used as the first insulating layer IL1 may include silicon oxide (SiOₓ), silicon nitride (SiNₓ), silicon oxynitride (SiOₓN_{y}), or the like. These may be used alone or in combination with each other. Examples of the organic insulating material that may be used as the first insulating layer IL1 may include a polyacryl-based resin, a polyimide-based resin, a polyamide-based resin, a siloxane-based resin, an acrylic-based resin, an epoxy-based resin, or the like. These may be used alone or in combination with each other.

The connection electrode CNE may be arranged on the substrate SUB. The connection electrode CNE may be arranged or disposed in the contact hole defined in the first insulating layer IL1. The connection electrode CNE may be connected to the pixel driving circuit CP. The connection electrode CNE may electrically connect the pixel driving circuit CP and the pixel electrode PE. The connection electrode CNE may include a metal, an alloy, a conductive metal nitride, a conductive metal oxide, a transparent conductive oxide, or the like. Examples of materials that may be used as the connection electrode CNE may include silver (Ag), alloys containing silver, molybdenum (Mo), alloys containing molybdenum, aluminum (Al), alloys containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The pixel electrode PE may be arranged on the first insulating layer IL1 and the connection electrode CNE. The pixel electrode PE may overlap each of the first to third light-emitting areas EA1, EA2, and EA3. The pixel electrode PE may be electrically connected to the pixel driving circuit CP through the connection electrode CNE. The pixel electrode PE may include a metal, an alloy, a conductive metal nitride, a conductive metal oxide, a transparent conductive oxide, or the like. These may be used alone or in combination with each other. In an embodiment, for example, the pixel electrode PE may serve as an anode electrode.

The second insulating layer IL2 may be arranged on the first insulating layer IL1. The second insulating layer IL2 may cover an edge of the pixel electrode PE, and may expose an upper surface of the pixel electrode PE. The second insulating layer IL2 may include an organic insulating material. Examples of the organic insulating material that may be used as the second insulating layer IL2 may include a polyacryl-based resin, a polyimide-based resin, a polyamide-based resin, a siloxane-based resin, an acrylic-based resin, an epoxy-based resin, or the like. These may be used alone or in combination with each other.

The light-emitting layer EML may be arranged on the pixel electrode PE and the second insulating layer IL2. In an embodiment, the light-emitting layer EML may extend continuously along the first to third light-emitting areas EA1, EA2, and EA3. However, the disclosure is not limited thereto, and the light-emitting layer EML may be independently arranged in each of the first to third light-emitting areas EA1, EA2, and EA3. The light-emitting layer EML may include an organic material that emits light of a color (e.g., a predetermined color). In an embodiment, the light-emitting layer EML may include an organic light-emitting material that emits white light, but the disclosure is not limited thereto.

The common electrode CE may be arranged on the light-emitting layer EML. The common electrode CE may extend continuously along the first to third light-emitting areas EA1, EA2, and EA3. The common electrode CE may include a metal, an alloy, a conductive metal nitride, a conductive metal oxide, a transparent conductive oxide, or the like. These may be used alone or in combination with each other. In an embodiment, for example, the common electrode CE may serve as a cathode electrode.

The encapsulation layer TFE may be arranged on the common electrode CE. The encapsulation layer TFE may effectively prevent impurities, moisture, or the like from penetrating into the light-emitting element LD from the outside. The encapsulation layer TFE may include at least one inorganic encapsulation layer and at least one organic encapsulation layer. In an embodiment, for example, the inorganic encapsulation layer may include silicon oxide (SiOₓ), silicon nitride (SiNₓ), silicon oxynitride (SiOₓN_{y}), or the like. These may be used alone or in combination with each other. In an embodiment, for example, the organic encapsulation layer may include a polymer cured material such as polyacrylate. In an embodiment, the encapsulation layer TFE may include a first inorganic encapsulation layer TFE1, an organic encapsulation layer TFE2, and a second inorganic encapsulation layer TFE3 that are sequentially stacked along the third direction DR3.

The first inorganic encapsulation layer TFE1 may be arranged on the common electrode CE. The first inorganic encapsulation layer TFE1 may cover the common electrode CE, and may be arranged along the profile of the common electrode CE with a substantially uniform thickness. The first inorganic encapsulation layer TFE1 may effectively prevent the light-emitting element LD from being deteriorated due to penetrating of impurities, moisture, or the like. In addition, the first inorganic encapsulation layer TFE1 may protect the light-emitting element LD from external impact. In an embodiment, for example, the first inorganic encapsulation layer TFE1 may include an inorganic material having flexibility.

The organic encapsulation layer TFE2 may be arranged on the first inorganic encapsulation layer TFE1. The organic encapsulation layer TFE2 may compensate for a step difference of the first inorganic encapsulation layer TFE1. Accordingly, the organic encapsulation layer TFE2 may have a substantially flat upper surface. The organic encapsulation layer TFE2 may protect the light-emitting element LD from external impact together with the first inorganic encapsulation layer TFE1. In an embodiment, for example, the organic encapsulation layer TFE2 may include an organic material having flexibility.

The second inorganic encapsulation layer TFE3 may be arranged on the organic encapsulation layer TFE2. The second inorganic encapsulation layer TFE3 may effectively prevent the light-emitting element LD from being deteriorated due to penetration of impurities, moisture, etc. together with the first inorganic encapsulation layer TFE1. In addition, the second inorganic encapsulation layer TFE3 may protect the light-emitting element LD from external impact together with the first inorganic encapsulation layer TFEL and the organic encapsulation layer TFE2. In an embodiment, for example, the second inorganic encapsulation layer TFE3 may include an inorganic material having flexibility.

The color filter layer CFL may be arranged on the encapsulation layer TFE. The color filter layer CFL may include a first color filter CF1, a second color filter CF2, and a third color filter CF3 that transmit light of different colors.

The first color filter CF1 may overlap the first light-emitting area EA1. The first color filter CF1 may transmit the second light among the first light emitted from the light-emitting layer EML, and may absorb or block the third light and the fourth light. In an embodiment, for example, the first color filter CF1 may transmit red light, and may absorb or block green light and blue light. However, the disclosure is not limited thereto.

The second color filter CF2 may overlap the second light-emitting area EA2. The second color filter CF2 may transmit the third light among the first light emitted from the light-emitting layer EML, and may absorb or block the second light and the fourth light. In an embodiment, for example, the second color filter CF2 may transmit green light, and may absorb or block red light and blue light. However, the disclosure is not limited thereto.

The third color filter CF3 may overlap the third light-emitting area EA3. The third color filter CF3 may transmit the fourth light among the first light emitted from the light-emitting layer EML, and may absorb or block the second light and the third light. In an embodiment, for example, the third color filter CF3 may transmit blue light, and may absorb or block red light and green light. However, the disclosure is not limited thereto.

The first color filter CF1 and the second color filter CF2 may overlap each other in the light blocking area BA located between the first light-emitting area EA1 and the second light-emitting area EA2. In addition, the second color filter CF2 and the third color filter CF3 may overlap each other in the light blocking area BA located between the second light-emitting area EA2 and the third light-emitting area EA3. In addition, although not illustrated in FIG. 4, the first color filter CF1 and the third color filter CF3 may overlap each other in the light blocking area BA located between the first light-emitting area EA1 and the third light-emitting area EA3. That is, a portion where different color filters overlap may overlap the light blocking area BA in a plan view. The portion of the color filter layer CFL where different color filters overlap each other may function as a light blocking pattern that blocks light. In an embodiment, the color filter layer CFL may include a black matrix pattern that overlaps the light blocking area BA in a plan view and includes an organic material including a light blocking material. In an embodiment, for example, the light blocking material may include a black pigment, a black dye, carbon black, or the like.

The flattening layer OVC may be arranged on the color filter layer CFL. The flattening layer OVC may flatten (or provide a flat surface on) a step difference of the color filter layer CFL. The flattening layer OVC may include an inorganic insulating material or an organic insulating material.

The lens layer LL may be arranged on the flattening layer OVC. The lens layer LL may include a plurality of micro lenses ML. The micro lenses ML may overlap the first light-emitting area EA1, the second light-emitting area EA2, and the third light-emitting area EA3, respectively. In addition, the micro lenses ML may overlap the first color filter CF1, the second color filter CF2, and the third color filter CF3, respectively, in a plan view. The micro lenses ML may improve light extraction efficiency. The micro lenses ML may have a refractive index (e.g., a predetermined refractive index). In an embodiment, for example, the micro lenses ML may have a refractive index greater than or equal to about 1.5 and less than or equal to about 1.7, but the disclosure is not limited thereto.

The filling layer FIL may be arranged on the lens layer LL. The filling layer FIL may flatten a step difference of the lens layer LL. The filling layer FIL may include an inorganic insulating material or an organic insulating material.

The encapsulation substrate ENC may be arranged on the filling layer FIL. The encapsulation substrate ENC may include a transparent material. In an embodiment, for example, the encapsulation substrate ENC may include glass or plastic.

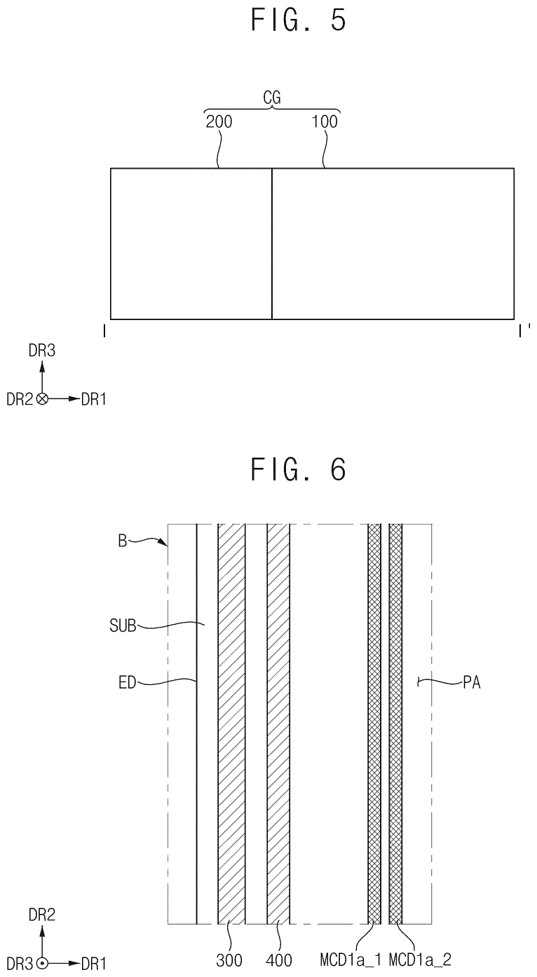

FIG. 5 is a cross-sectional view taken along line I-I′ of FIG. 1.

Referring to FIGS. 1 and 5, an embodiment of the display device DD may include a chip structure CS. The chip structure CS may be arranged on the substrate SUB in the display area DA and the peripheral area PA adjacent to the display area DA. The chip structure CS may include a semiconductor chip 100 and a guard ring 200.

In an embodiment, for example, the semiconductor chip 100 may be a logic chip, a memory chip, or the like. In an embodiment where the semiconductor chip 100 is a logic chip, the logic chip may be designed in various ways in consideration of the operations to be performed. In an embodiment where the semiconductor chip 100 is a memory chip, the memory chip may be a non-volatile memory chip. In an embodiment, the memory chip may be a flash memory chip. In an embodiment, for example, the memory chip may be one of a NAND flash memory chip or a NOR flash memory chip. However, the disclosure is not limited thereto, the memory chip may also be a phase-change random access memory (PRAM), a magneto-resistive random access memory (MRAM), or a resistive random access memory (RRAM).

The semiconductor chip 100 may include various elements. In an embodiment, for example, the semiconductor chip 100 may include active elements and/or passive elements. In an embodiment, the semiconductor chip 100 may include a metal oxide semiconductor field effect transistor (MOSFET) such as a complementary metal oxide semiconductor (CMOS) transistor, a system large scale integration (LSI), an image sensor such as CMOS image sensor (CIS), a micro-electromechanical system (MEMS), or the like.

The guard ring 200 may be arranged adjacent to the semiconductor chip 100. In an embodiment, for example, the guard ring 200 may surround a side surface of the semiconductor chip 100 in a plan view. In FIG. 5, an embodiment where the guard ring 200 is arranged in an opposite direction of the first direction DR1 from the semiconductor chip 100 is shown as an example, but the disclosure is not limited thereto. The guard ring 200 may include a metal. In an embodiment, for example, the guard ring 200 may include a metal seal.

A wafer (WA, refer to FIG. 9) may be separated into a plurality of semiconductor chips 100 along a scribing line (SL, refer to FIG. 9). Cracks may occur in the wafer during a sawing process to separate the wafer into the semiconductor chips 100.

The guard ring 200 may effectively prevent the cracks that may occur during the sawing process from being transmitted to the semiconductor chip 100, or a foreign material (e.g., ionic contaminants, etc.) from being transmitted to the semiconductor chip 100 through the cracks. In addition, the guard ring 200 may provide a low resistance path for surge current. Here, the surge current may refer to a current that may damage an element (e.g., the light-emitting element LD of FIG. 4) by dissipating thermal energy. That is, the guard ring 200 may dissipate abnormal electromagnetic interference (EMI) noise such as the surge current to the outside, and may effectively prevent the element from being damaged.

FIG. 6 is an enlarged plan view of area B of FIG. 1. Particularly, FIG. 6 is an enlarged plan view of the peripheral area PA adjacent to the edge ED of the substrate SUB. FIG. 7 is a cross-sectional view illustrating a first blocking structure, a second blocking structure, and a crack detection structure included in the display device of FIG. 1.

Referring to FIGS. 1, 6, and 7, an embodiment of the display device DD may include a first blocking structure 300, a second blocking structure 400, and a crack detection structure 500. The crack detection structure 500 may include the first crack detection line MCD1a_1 and the second crack detection line MCD1a_2.

In an embodiment, as illustrated in FIG. 6, the first blocking structure 300, the second blocking structure 400, and the crack detection structure 500 may be sequentially arranged along the first direction DR1 from the edge ED of the substrate SUB. In addition, although not illustrated in FIGS. 1 and 6, the first blocking structure 300, the second blocking structure 400, and the crack detection structure 500 may be arranged sequentially along the opposite direction of the first direction DR1, the second direction DR2, and the opposite direction of the second direction DR2 from the edge ED of the substrate SUB. Each of the first blocking structure 300, the second blocking structure 400, and the crack detection structure 500 may surround the display area DA in a plan view. The second blocking structure 400 may surround the crack detection structure 500 in a plan view, and the first blocking structure 300 may surround the second blocking structure 400 in a plan view.

The first blocking structure 300 may be arranged on the substrate SUB, and may be arranged along the edge ED of the substrate SUB in a plan view. The first blocking structure 300 may block the propagation of cracks during sawing and packaging processes.

In an embodiment, as illustrated in FIG. 7, the first blocking structure 300 may include a plurality of line layers, a plurality of vias 320, and a cover pad 319.

The plurality of line layers may include first to eighth line layers 311, 312, 313, 314, 315, 316, 317, and 318 sequentially stacked along the third direction DR3. Each of the first to eighth line layers 311, 312, 313, 314, 315, 316, 317, and 318 may include a metal. In an embodiment, the first to eighth line layers 311, 312, 313, 314, 315, 316, 317, and 318 may include the same metal as each other. In an embodiment, for example, each of the first to eighth line layers 311, 312, 313, 314, 315, 316, 317, and 318 may include aluminum (Al) or copper (Cu). These may be used alone or in combination with each other. However, the disclosure is not limited thereto, and the first to eighth line layers 311, 312, 313, 314, 315, 316, 317, and 318 may include different materials.

In an embodiment, as shown in FIG. 7, the line layers of the first blocking structure 300 may include eight metal layers, but the disclosure is not limited thereto. The number of metal layers included in the line layers of the first blocking structure 300 may be varied according to embodiments.

A metal insulating layer may be arranged between the line layers and the cover pad 319. The metal insulating layer may be an inter metal dielectric (IMD) having a small dielectric constant (i.e., low-k). The metal insulating layer may effectively prevent short circuit between the first to eighth line layers 311, 312, 313, 314, 315, 316, 317, and 318 and the cover pad 319.

The plurality of vias 320 may be defined in the metal insulating layer. Each of the vias 320 may electrically connect the line layers. In an embodiment, for example, the via 320 may be arranged between the first line layer 311 and the second line layer 312, between the second line layer 312 and the third line layer 313, between the third line layer 313 and the fourth line layer 314, between the fourth line layer 314 and the fifth line layer 315, between the fifth line layer 315 and the sixth line layer 316, between the sixth line layer 316 and the seventh line layer 317, between the seventh line layer 317 and the eighth line layer 318, and between the eighth line layer 318 and the cover pad 319.

Each of the vias 320 may include a chemical-resistant metal material. In an embodiment, for example, each of the vias 320 may include tungsten (W). However, the disclosure is not limited thereto.

The cover pad 319 may be arranged on the line layers. In an embodiment, for example, the cover pad 319 may be arranged on the eighth line layer 318. The cover pad 319 may effectively prevent the line layers of the first blocking structure 300 arranged under the cover pad 319 from being damaged in a subsequent process. In an embodiment, for example, the cover pad 319 may include titanium (Ti), tantalum (Ta), titanium nitride (TiN), or the like. However, the disclosure is not limited thereto. In another embodiment, the cover pad 319 may be omitted.

The second blocking structure 400 may be arranged on the substrate SUB, and may be located between the display area DA and the first blocking structure 300 in a plan view. In an embodiment, the second blocking structure 400 may be located between the first blocking structure 300 and the crack detection structure 500 in a plan view. In an embodiment, for example, the second blocking structure 400 may be located between the first blocking structure 300 and the first crack detection line MCD1a_1 in a plan view. The second blocking structure 400 may block moisture from flowing into the semiconductor chip through a scribing line (SL, refer to FIG. 9) during a back grinding process.

In an embodiment, as illustrated in FIG. 7, the second blocking structure 400 may include a plurality of line layers, a plurality of vias 420, and a cover pad 419.

The plurality of line layers may include first to eighth line layers 411, 412, 413, 414, 415, 416, 417, and 418 sequentially stacked along the third direction DR3. Each of the first to eighth line layers 411, 412, 413, 414, 415, 416, 417, and 418 may include a metal. In an embodiment, the first to eighth line layers 411, 412, 413, 414, 415, 416, 417, and 418 may include the same metal as each other. In an embodiment, for example, each of the first to eighth line layers 411, 412, 413, 414, 415, 416, 417, and 418 may include aluminum (Al) or copper (Cu). These may be used alone or in combination with each other. However, the disclosure is not limited thereto, and the first to eighth line layers 411, 412, 413, 414, 415, 416, 417, and 418 may include different materials.

In an embodiment, as shown in FIG. 7, the line layers of the second blocking structure 400 may include eight metal layers, but the disclosure is not limited thereto. The number of metal layers included in the line layers of the second blocking structure 400 may be varied according to embodiments.

The metal insulating layer may be arranged between the line layers and the cover pad 419. The plurality of vias 420 may be defined in the metal insulating layer. Each of the vias 420 may electrically connect the line layers. In an embodiment, for example, the via 420 may be arranged between the first line layer 411 and the second line layer 412, between the second line layer 412 and the third line layer 413, between the third line layer 413 and the fourth line layer 414, and between the fourth line layer 414 and the fifth line layer 415, between the fifth line layer 415 and the sixth line layer 416, between the sixth line layer 416 and the seventh line layer 417, between the seventh line layer 417 and the eighth line layer 418, and between the eighth line layer 418 and the cover pad 419.

Each of the vias 420 may include a chemical-resistant metal material. In an embodiment, for example, each of the vias 420 may include tungsten (W). However, the disclosure is not limited thereto.

The cover pad 419 may be arranged on the line layers. In an embodiment, for example, the cover pad 419 may be arranged on the eighth line layer 418. The cover pad 419 may effectively prevent the line layers of the second blocking structure 400 arranged under the cover pad 419 from being damaged in a subsequent process. In an embodiment, for example, the cover pad 419 may include titanium (Ti), tantalum (Ta), titanium nitride (TiN), or the like. However, the disclosure is not limited thereto. In an embodiment, the cover pad 419 may be omitted.

The crack detection structure 500 may be arranged on the substrate SUB, and may be located between the display area DA and the second blocking structure 400 in a plan view. The crack detection structure 500 may be spaced apart from the first blocking structure 300 and the second blocking structure 400. In an embodiment, for example, an in-plane separation distance between the crack detection structure 500 and the second blocking structure 400 may be about 10 micrometers. However, the disclosure is not limited thereto. The crack detection structure 500 may detect cracks that are not blocked by the first blocking structure 300 and the second blocking structure 400.

In an embodiment, as illustrated in FIG. 7, the crack detection structure 500 may include lower line layers BML, middle line layers MML, upper line layers UML, a plurality of vias 520, a detection line connection electrodes MCE, and a cover pad 519. In an embodiment, for example, the lower line layers BML may include first to fourth line layers 511, 512, 513, and 514, the middle line layers MML may include a fifth line layer 515 and a sixth line layer 516, and the upper line layers UML may include a seventh line layer 517 and an eighth line layer 518.

The first to eighth line layers 511, 512, 513, 514, 515, 516, 517, and 518 may be sequentially stacked along the third direction DR3. Each of the first to eighth line layers 511, 512, 513, 514, 515, 516, 517, and 518 may include a metal. In an embodiment, the first to eighth line layers 511, 512, 513, 514, 515, 516, 517, and 518 may include the same metal as each other. In an embodiment, for example, each of the first to eighth line layers 511, 512, 513, 514, 515, 516, 517, and 518 may include aluminum (Al) or copper (Cu). These may be used alone or in combination with each other. However, the disclosure is not limited thereto, and the first to eighth line layers 511, 512, 513, 514, 515, 516, 517, and 518 may include different materials.

In an embodiment, as shown in FIG. 7, the line layers of the crack detection structure 500 may include eight metal layers, but the disclosure is not limited thereto. The number of metal layers included in the line layers of the crack detection structure 500 may be varied according to embodiments.

The metal insulating layer may be arranged between the line layers and the cover pad 519. The plurality of vias 520 may be defined in the metal insulating layer. Each of the vias 520 may electrically connect the line layers. In an embodiment, the via 520 may be arranged between the first line layer 511 and the second line layer 512, between the second line layer 512 and the third line layer 513, and between the third line layer 513 and the fourth line layer 514, between the fourth line layer 514 and the fifth line layer 515, between the sixth line layer 516 and the seventh line layer 517, between the seventh line layer 517 and the eighth line layer 518, and between the eighth line layer 518 and the cover pad 519 may be arranged.

Each of the vias 520 may include a chemical-resistant metal material. In an embodiment, for example, each of the vias 520 may include tungsten (W). However, the disclosure is not limited thereto.

In an embodiment, the middle line layers MML may include crack detection lines. In an embodiment, for example, the middle line layers MML may include the first crack detection line MCD1a_1 and the second crack detection line MCD1a_2. In an embodiment, the second crack detection line MCD1a_2 may be arranged on the first crack detection line MCD1a_1. In an embodiment, for example, the first crack detection line MCD1a_1 may be arranged in a same layer as the fifth line layer 515, and the second crack detection line MCD1a_2 may be arranged in a same layer as the sixth line layer 516. However, the disclosure is not limited thereto. In an embodiment, the second crack detection line MCD1a_2 may be arranged under the first crack detection line MCD1a_1. In an embodiment, for example, the first crack detection line MCD1a_1 may be arranged in the same layer as the sixth line layer 516, and the second crack detection line MCD1a_2 may be arranged in the same layer as the fifth line layer 515.

In an embodiment, the first crack detection line MCD1a_1, the second crack detection line MCD1a_2, the fifth line layer 515, and the sixth line layer 516 may include a same metal as each other. In an embodiment, for example, each of the first crack detection line MCD1a_1, the second crack detection line MCD1a_2, the fifth line layer 515, and the sixth line layer 516 may include aluminum (Al) or copper (Cu). These may be used alone or in combination with each other. However, the disclosure is not limited thereto.

The detection line connection electrode MCE may be arranged in the metal insulating layer arranged between the fifth line layer 515 and the sixth line layer 516. The detection line connection electrode MCE may contact the first crack detection line MCD1a_1 and the second crack detection line MCD1a_2. Accordingly, the detection line connection electrode MCE may electrically connect the first crack detection line MCD1a_1 and the second crack detection line MCD1a_2. In an embodiment, the detection line connection electrode MCE may include a same metal as the vias 520. In an embodiment, for example, each of the detection line connection electrode MCE and the vias 520 may include tungsten (W). However, the disclosure is not limited thereto.

The cover pad 519 may be arranged on the line layers. In an embodiment, for example, the cover pad 519 may be arranged on the eighth line layer 518. The cover pad 519 may effectively prevent the line layers of the crack detection structure 500 arranged under the cover pad 519 from being damaged in a subsequent process. In an embodiment, for example, the cover pad 519 may include titanium (Ti), tantalum (Ta), titanium nitride (TiN), or the like. However, the disclosure is not limited thereto.

In a case where the crack detection line is arranged in the lower line layers BML of the crack detection structure 500, a problem in which the crack is not detected may occur if the crack does not propagate to the lower line layers BML. For example, when the first crack detection line MCD1a_1 is arranged in a same layer as the first line layer 511 and the second crack detection line MCD1a_2 is arranged in a same layer as the second line layer 512, a problem in which the crack is not detected may occur if the crack does not propagate to the first line layer 511 and the second line layer 512. In other words, when the crack detection line is arranged in the lower line layers BML of the crack detection structure 500, the sensitivity of detecting the crack may be relatively low.

In a case where the crack detection line is arranged in the upper line layers UML of the crack detection structure 500, a problem in which even an insignificant crack is detected may occur. For example, when the first crack detection line MCD1a_1 is arranged in the same layer as the seventh line layer 517, and the second crack detection line MCD1a_2 is arranged in the same layer as the eighth line layer 518, a problem in which even the insignificant crack is detected may occur. In other words, when the crack detection line is arranged in the upper line layers UML of the crack detection structure 500, the sensitivity of detecting the crack may be relatively high.

According to an embodiment of the disclosure, the crack detection line may be arranged in the middle line layers MML of the crack detection structure 500. In an embodiment, for example, the first crack detection line MCD1a_1 may be arranged in the same layer as the fifth line layer 515, and the second crack detection line MCD1a_2 may be arranged in a same layer as the sixth line layer 516. In such an embodiment, as the crack detection line is arranged in the middle line layers MML of the crack detection structure 500, the crack detection structure 500 may detect cracks that are not blocked by the first blocking structure 300 and the second blocking structure 400 with appropriate or desired crack detection sensitivity.

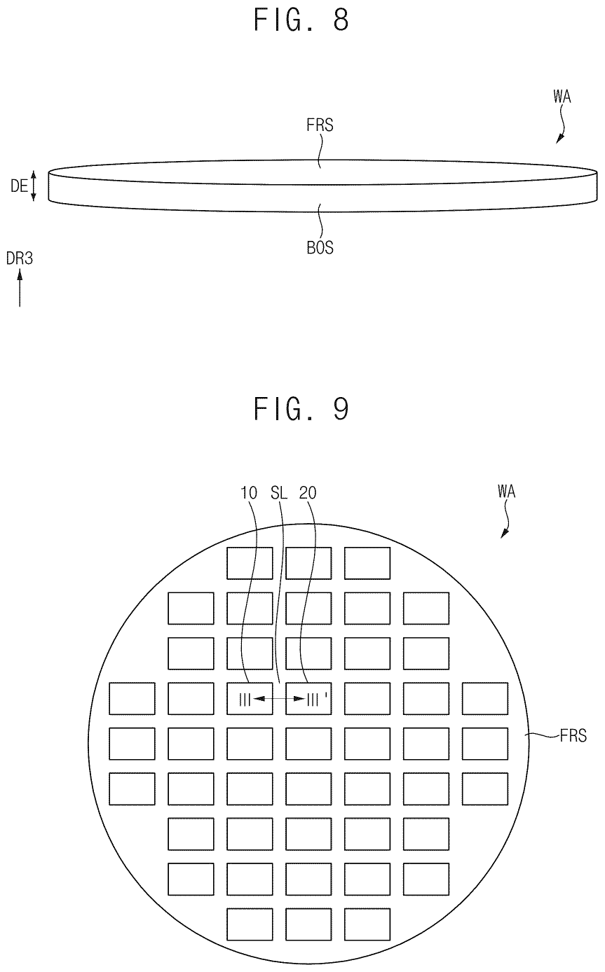

FIGS. 8, 9, 10, and 11 are views illustrating an embodiment of a method of manufacturing the display device of FIG. 1. Hereinafter, any repetitive detailed descriptions of the elements of the display device DD the same as those described above with reference to FIGS. 1 to 7 may be omitted or may be simplified.

Referring to FIGS. 8, 9, and 10, a substrate may be formed from a wafer WA. In an embodiment, the wafer WA may include silicon. In an embodiment, for example, the wafer WA may be a monocrystalline silicon wafer, a polycrystalline silicon wafer, or an amorphous silicon wafer.

The wafer WA may have a front surface FRS and a back surface BOS. A semiconductor pattern may be formed on the front surface FRS of the wafer WA. In an embodiment, for example, the substrate may be a silicon semiconductor substrate formed through a CMOS process.

A layer including the light-emitting element LD, the encapsulation layer TFE, the color filter layer CFL, or the like which are illustrated in FIG. 4 may be arranged or sequentially formed on the substrate. In an embodiment, the display device DD may be an OLEDOS in which an organic light-emitting element is arranged on the silicon semiconductor substrate.

A thickness DE of the wafer WA may be controlled through a back grinding process, organic light emitting diode on silicon example, the thickness DE of the wafer WA may be thinned by removing a portion of the back surface BOS of the wafer WA in the back grinding process.

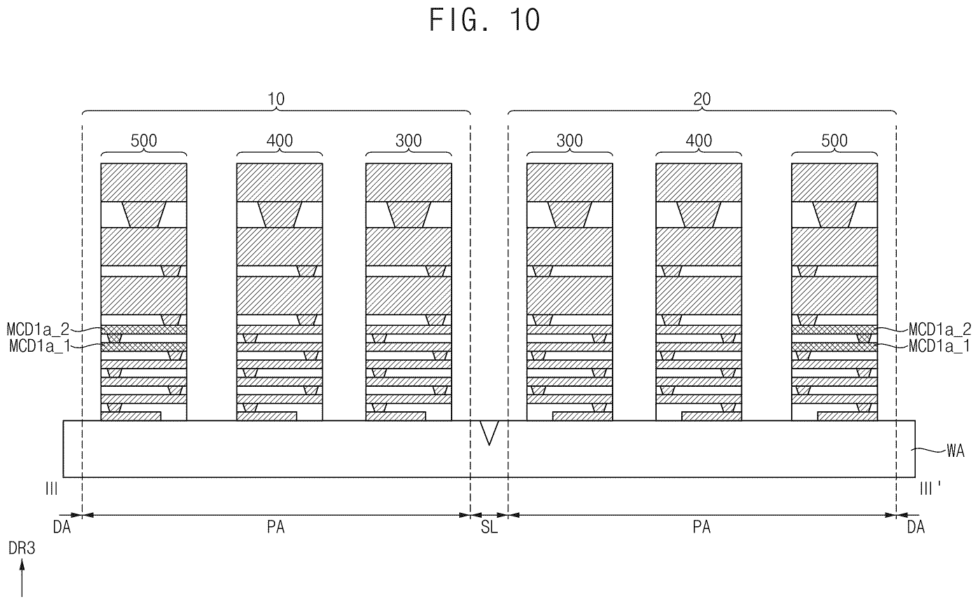

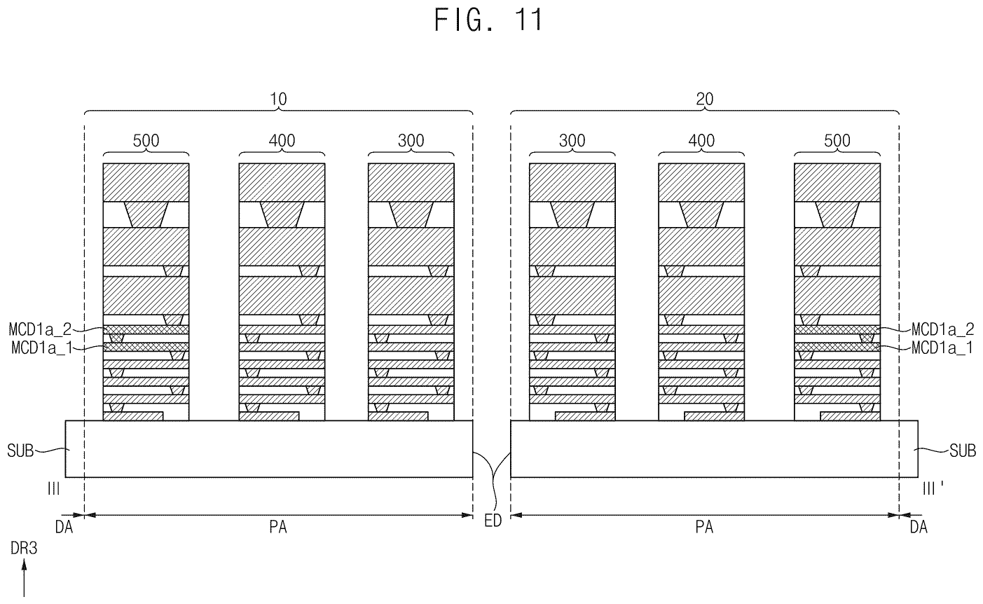

In an embodiment, as illustrated in FIGS. 9 and 10, a scribing line SL may be defined or formed on the wafer WA. The scribing line SL may be located between semiconductor chips 10 and 20 in a plan view. The scribing line SL may be formed to a depth of about half of the thickness DE of the wafer WA.

The first blocking structure 300 and the second blocking structure 400 may be formed on the wafer WA. The first blocking structure 300 may be formed adjacent to the scribing line SL. The first blocking structure 300 may block a crack from propagating toward the display area DA during a process of separating the individual semiconductor chips 10 and 20 along the scribing line SL. The second blocking structure 400 may be formed between the first blocking structure 300 and the display area DA. The second blocking structure 400 may be spaced apart from the scribing line SL by the first blocking structure 300. The second blocking structure 400 may block moisture from penetrating toward the display area DA during the back grinding process.

The crack detection structure 500 may be formed on the wafer WA. The crack detection structure 500 may be formed between the second blocking structure 400 and the display area DA. The crack detection structure 500 may be spaced apart from the first blocking structure 300 and the second blocking structure 400. The middle line layers (MML, refer to FIG. 7) of the crack detection structure 500 may include the first crack detection line MCD1a_1 and the second crack detection line MCD1a_2.

Referring to FIG. 11, the wafer WA may be separated into the semiconductor chips 10 and 20. In an embodiment, for example, the wafer WA may be separated into the semiconductor chips 10 and 20 through sawing and packaging processes. When cracks occurs in the wafer WA during a process of cutting the wafer WA, the crack detection structure 500 may detect the cracks that are not blocked by the first blocking structure 300 and the second blocking structure 400.

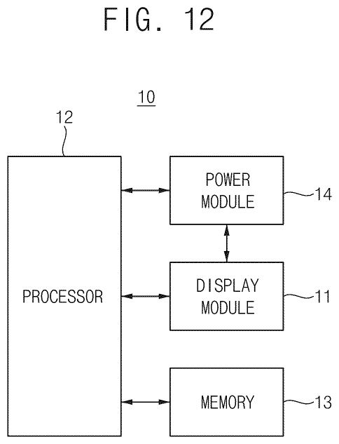

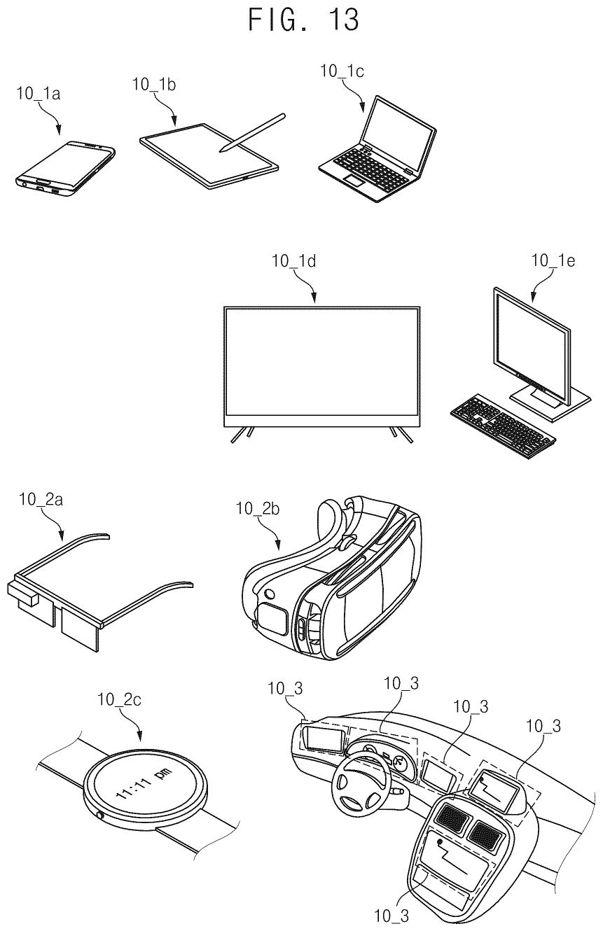

FIG. 12 is a block diagram of an electronic device according to an embodiment of the disclosure.

Referring to FIG. 12, an electronic device 10 according to an embodiment may include a display module 11, a processor 12, a memory 13, and a power module 14. The display device according to an embodiment may be applied to a variety of electronic devices. The electronic device 10 according to an embodiment may include the display device described above, and may further include modules or devices having other additional functions in addition to the display device.

The processor 12 may include at least one selected from a central processing unit (CPU), an application processor (AP), a graphic processing unit (GPU), a communication processor (CP), an image signal processor (ISP), and a controller.

The memory 13 may store data information required for operation of the processor 12 or the display module 11. When the processor 12 executes an application stored in the memory 13, an image data signal and/or a input control signal may be transmitted to the display module 11, and the display module 11 may process the received signals and may output image information through a display screen.

The power module 14 may include a power supply module, such as a power adapter or a battery device, etc., and a power conversion module that converts power supplied by the power supply module to generate the power required for operation of the electronic device 10. That is, the power module 14 may provide power to the display device according to the embodiments described above.

At least one of the components of the electronic device 10 described above may be included in the display device according to the embodiments described above. In addition, some of the individual modules that are functionally included in one module may be included in the display device and others may be provided separately from the display device. In an embodiment, for example, the display device may include the display module 11, and the processor 12, the memory 13, and the power module 14 may be provided in the form of other devices in the electronic device 10 other than the display device.

FIG. 13 is a schematic diagram of an electronic device according to various embodiments.

Referring to FIG. 13, various embodiments of an electronic device to which a display device is applied may include image display electronic devices such as a smartphones 10_1a, a tablet PC 10_1b, a laptop 10_1c, a television 10_1d, a desk monitor 10_1e, or the like, wearable electronic devices including display modules such as a smart glasses 10_2a, a head-mounted display 10_2b, and a smart watch 10_2c, or the like, and vehicle electronic devices 10_3 including display modules such as a CID (center information display) which may be disposed on a instrument panel, a center fascia, and a dashboard of an automobile and a room mirror display, or the like.

Embodiments of the disclosure may be applied to various display devices, for example, display devices for vehicles, ships and aircraft, portable communication devices, display devices for exhibition or information transmission, medical display devices, and the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate comprising a display area and a peripheral area surrounding the display area;
a plurality of sub-pixels disposed on the substrate in the display area;
a first blocking structure disposed on the substrate in the peripheral area along an edge of the substrate in a plan view, wherein the first blocking structure blocks crack propagation;
a second blocking structure disposed on the substrate in the peripheral area between the display area and the first blocking structure in the plan view, wherein the second blocking structure blocks moisture; and
a crack detection structure disposed on the substrate in the peripheral area between the display area and the second blocking structure in the plan view,
wherein the crack detection structure comprises:
a lower line layer disposed on the substrate;
a middle line layer which is disposed on the lower line layer and comprises a crack detection line; and
an upper line layer disposed on the middle line layer.

2. The display device of claim 1, wherein the crack detection structure is spaced apart from the first blocking structure and the second blocking structure in the plan view.

3. The display device of claim 1,
wherein the second blocking structure surrounds the crack detection structure in the plan view, and
wherein the first blocking structure surrounds the second blocking structure in the plan view.

4. The display device of claim 1, further comprising:
a crack detection circuit disposed on the substrate in the peripheral area,
wherein the crack detection line comprises:
a first crack detection line which receives a test voltage; and
a second crack detection line, wherein a first end of the second crack detection line is electrically connected to the first crack detection line, and a second end of the second crack detection line, which is opposite to the first end, is electrically connected to the crack detection circuit.

5. The display device of claim 4, wherein the second crack detection line is disposed on the first crack detection line.

6. The display device of claim 4,
wherein the crack detection structure comprises first to eighth line layers sequentially stacked on the substrate,
wherein the lower line layer comprises the first to fourth line layers,
wherein the middle line layer comprises the fifth line layer and the sixth line layer, and
wherein the upper line layer comprises the seventh line layer and the eighth line layer.

7. The display device of claim 6,
wherein the first crack detection line is disposed in a same layer as the fifth line layer, and
wherein the second crack detection line is disposed in a same layer as the sixth line layer.

8. The display device of claim 1, wherein the substrate comprises a silicon wafer.

9. A display device comprising:
a substrate including a display area and a peripheral area surrounding the display area;
a plurality of sub-pixels disposed on the substrate in the display area;
a blocking structure disposed on the substrate in the peripheral area along an edge of the substrate to surrounding the display area in a plan view;
a crack detection structure disposed on the substrate in the peripheral area between the display area and the blocking structure in the plan view, wherein the crack detection structure comprises a lower line layer disposed on the substrate, a middle line layer which is disposed on the lower line layer and comprises a crack detection line, and an upper line layer disposed on the middle line layer;
a plurality of pads disposed on the substrate in the peripheral area to be adjacent to the edge of the substrate in the plan view;
a crack detection circuit disposed on the substrate in the peripheral between the display area and the plurality of pads in the plan view, and electrically connected to the crack detection line; and
a demux portion disposed on the substrate in the peripheral area between the display area and the crack detection circuit in the plan view.

10. The display device of claim 9, wherein the crack detection structure is spaced apart from the blocking structure in the plan view.

11. The display device of claim 9, wherein the blocking structure surrounds the crack detection structure in the plan view.

12. The display device of claim 9, wherein the crack detection line comprises:
a first crack detection line which receives a test voltage; and
a second crack detection line, wherein a first end of the second crack detection line is electrically connected to the first crack detection line, and a second end of the second crack detection line is, which is opposite to the first end, is electrically connected to the crack detection circuit.

13. The display device of claim 12, wherein at least one of the plurality of pads provide the test voltage to the first crack detection line.

14. The display device of claim 12, wherein the second crack detection line is disposed on the first crack detection line.

15. The display device of claim 12, further comprising:
a plurality of fan out lines disposed on the substrate in the peripheral area at a lower side of the demux portion in the plan view, and
a plurality of data lines disposed on the substrate in the display area and connected to the plurality of sub-pixels.

16. The display device of claim 15, wherein the crack detection circuit comprises:
a constant voltage line to which the test voltage is applied; and
a detection switch connected to each of the plurality of fan out lines.

17. The display device of claim 16,
wherein at least one of the plurality of fan out lines is electrically connected to the constant voltage line through the detection switch, and
wherein at least another one of the plurality of fan out lines is electrically connected to the second crack detection line through the detection switch.

18. The display device of claim 12,
wherein the crack detection structure comprises first to eighth line layers sequentially stacked on the substrate,
wherein the lower line layer comprises the first to fourth line layers,
wherein the middle line layer comprises the fifth line layer and the sixth line layer,
wherein the upper line layer comprises the seventh line layer and the eighth line layer,
wherein the first crack detection line is disposed in a same layer as the fifth line layer, and
wherein the second crack detection line is disposed in a same layer as the sixth line layer.

19. The display device of claim 9, further comprising:
a driving chip disposed on the substrate in the peripheral area and connected to the plurality of pads,
wherein the crack detection circuit is disposed between the demux portion and the driving chip in the plan view.

20. An electronic device comprising:
a display device comprising a plurality of sub-pixels; and
a processor which provides an image data signal and an input control signal to the display device,
wherein the display device comprises:
a substrate comprising a display area and a peripheral area surrounding the display area;
the plurality of sub-pixels disposed on the substrate in the display area;
a first blocking structure disposed on the substrate in the peripheral area along an edge of the substrate in a plan view, wherein the first blocking structure blocks crack propagation;
a second blocking structure disposed on the substrate in the peripheral area between the display area and the first blocking structure in the plan view, where the second blocking structure blocks moisture; and
a crack detection structure disposed on the substrate in the peripheral area between the display area and the second blocking structure in the plan view, wherein the crack detection structure comprises a lower line layer disposed on the substrate, a middle line layer which is disposed on the lower line layer and comprises a crack detection line, and an upper line layer disposed on the middle line layer.
